(19) United States
(12) Patent Application Publication
(10) Pub. No.: US 2013/0147129 A1
(43) Pub. Date: Jun. 13, 2013

(54) WAFER SUPPORTING STRUCTURE

(71) Applicant: Chui Fu Chiu, Taoyuan City (TW)

(72) Inventor: Chui Fu Chiu, Taoyuan City (TW)

(73) Assignee: NAN YA TECHNOLOGY CORPORATION, Kueishan (TW)

(21) Appl. No.: 13/314,684

(22) Filed: Dec. 8, 2011

(51) Int. Cl. H01L 21/58; B25B 11/00

(52) U.S. Cl. 279/3; 269/296; 279/128

(57) ABSTRACT

A wafer supporting structure for improving the critical dimension uniformity of a wafer, including: a chuck, a plurality of pin holes, and a platform positioned under the chuck. The chick has a surface and configured to receive a wafer thereon, the plurality of pin holes form through the chuck, and the platform comprises a plurality of movable pieces which support corresponding pins, wherein the pins are configured to move in a direction perpendicularly protruding from or sinking into the surface of the chuck. The movable piece has one end supporting the bottom of the pin and the other end subjected to an pneumatic pressure, hydraulic pressure, or piezoelectricity.

### BACKGROUND OF THE INVENTION

1. Technical Field

The present invention relates to a structure configured to improve the critical dimension uniformity of a wafer, and more particularly, to a wafer supporting structure that can locally improve the critical dimension uniformity of a wafer.

2. Background

As the semiconductor industry enters the sub-0.1-micron regime, critical dimension (CD) control becomes increasingly important especially for the cross-wafer CD variation. Conventionally, industry uses the gate length in a transistor as a CD indicator, and the stringent control is raised to the three-sigma level (3σ) in terms of different technology nodes.

One source of the CD variation within a wafer is the inconsistency of the shape and thickness across the plain wafer. During the photolithography process, almost every step, including coating, baking, exposure, development and etching, exacerbates the abovementioned problem to the extent of generating elastic deformation that leads to significant in-plane distortion. These defects are carried into the subsequent lithography processes and cause overlay errors. An excessive CD variation will strongly affect the final chip-to-chip performance spread in terms of speed and power, thereby reducing the chip's profitability.

CD variation at lot-to-lot and wafer-to-wafer levels is generally solved by advanced process control (APC), that is, controlling wafer-averaged CD with schemes ranging from feed-forward to feed-forward/feedback closed-loop control. CD uniformity data is collected to correct perturbations from the photolithography process, including spatial variation of the exposure dose and post-exposure bake temperature profile tuning, both built in a well-designed process control framework. However, these methods demonstrate that neither modification of wafer morphology nor sensitive spatial control can be achieved. To address shortcomings of the conventional art, the present invention discloses a solution for CD uniformity improvement via mechanical correction of the wafer morphology utilizing the same CD uniformity data.

### SUMMARY

The present invention discloses an improved wafer supporting structure such as a vacuum chuck or an electrostatic chuck used in semiconductor manufacturing processes which alleviate problems caused by, for example, critical dimension uniformity. The improved wafer supporting structure comprises a chuck having a surface configured to receive a wafer thereon; a plurality of pin holes forming through the chuck; and a platform positioned under the chuck and supporting a plurality of movable pins, wherein the pins have axial lengths greater than the depth of the pin holes and cross-sectional areas equal to the cross-sectional area of the pin holes, and configured to move in a direction perpendicularly protruding from or sinking into the surface of the chuck.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention are illustrated with the following description and upon reference to the accompanying drawings in which:

FIG. 1 illustrates a top view of a wafer chuck implemented in one embodiment of the present invention, equipped with three vacuum holes (dark color) and a plurality of pin holes arranged in a radial fashion;

FIG. 2 illustrates a top view of a wafer used in one embodiment of the present invention with a plurality of shots projected on the wafer during a photolithography exposure process;

FIG. 3 illustrates a top view of a portion of a wafer chuck in another embodiment, wherein the portion of the chuck is defined by an area of a single shot shown in FIG. 2, and the portion of the chuck is equipped with an empty vacuum hole, a pin-containing vacuum hole, and three pin-containing pin holes;

FIG. 4 illustrates a cross-sectional view along the line 1-1′ shown in FIG. 3;

FIG. 5 illustrates a top view of a portion of a wafer chuck in another embodiment, wherein the portion of the chuck is defined by an area of a single shot shown in FIG. 2, and the portion of the chuck is equipped with an empty vacuum hole, a pin-containing vacuum hole, and a plurality of pin-containing pin holes of different size;

FIG. 6 illustrates a cross-sectional view along the line 2-2′ shown in FIG. 5;

FIG. 7 illustrates a top view of a portion of a wafer chuck in another embodiment, wherein the portion of the chuck is defined by an area of a single shot shown in FIG. 2, and the portion of the chuck is equipped with an empty vacuum hole, a pin-containing vacuum hole, and a plurality of pin-containing pin holes of different size; and

FIG. 8 illustrates a cross-sectional view along the line 3-3′ shown in FIG. 7.

### DETAILED DESCRIPTION

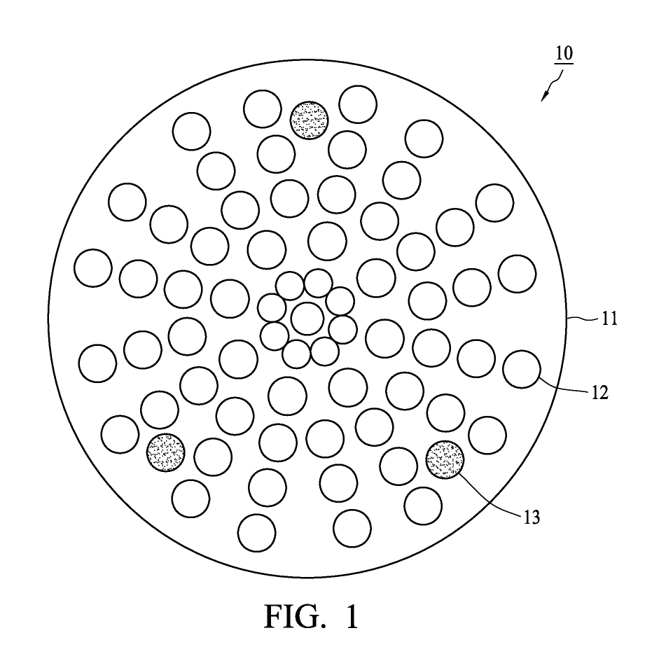

Embodiments of the present invention disclose a wafer supporting structure configured to correct the local morphology on a wafer by exerting mechanical force on the wafer. In a routine lithography process, the wafer supporting structure disclosed in the following is activated by a signal from a computer program to correct the local surface morphology after analyzing the CD uniformity data. The goal of the correction process is to achieve better cross-wafer uniformity on a testing wafer as well as on the subsequent wafers of the same batch. FIG. 1 illustrates a top view of a wafer supporting structure 10 with a wafer chuck 11 implemented in one embodiment of the present invention.

The wafer chuck 11 is equipped with three vacuum holes 13 and a plurality of pin holes 12 arranged in a radial fashion. The three vacuum holes 13 can be positioned on three vertices of a triangle, each with a diameter of, for example, 10 mm. The number and size of vacuum holes varies from supplier to supplier and thus different arrangement can be expected. The purpose of the vacuum holes is to exert a suction force on a wafer sitting thereupon, in order to carefully fix the position of the wafer moving along a track during semiconductor processing. The importance of precise control of the wafer position cannot be overstated since the photolithography process cannot afford the consequence of a macroscopic displacement of a wafer. The pin hole 12 on the wafer chuck 11 may be, for example, a hollow cylindrical opening that passes all the way thorough the wafer chuck 11. The pin hole 12 allows a pin (not shown in FIG. 1) to pass through from the bottom of the wafer chuck 11, so the pin can interact with the wafer positioned thereupon and mechanically correct the local wafer morphology.

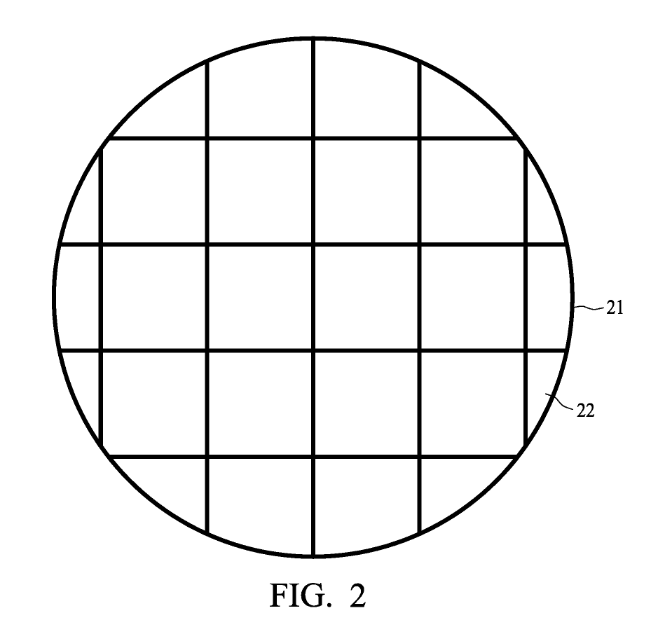

FIG. 2 illustrates a top view of a wafer 21 used in one embodiment of the present invention. A plurality of shots 22 are projected on the wafer 21 during a photolithography process. Within the area of one shot, the wafer directly corresponds to a plurality of pin holes 12 underneath. In other words, the arrangement of the pin holes 12 is repeated in the area defined by each shot 22. Each shot 22 may have at least one pin hole 12 or a set of pin holes 12 with identical arrangement positioned on the wafer chuck 11 which supports and fixes the wafer 21.

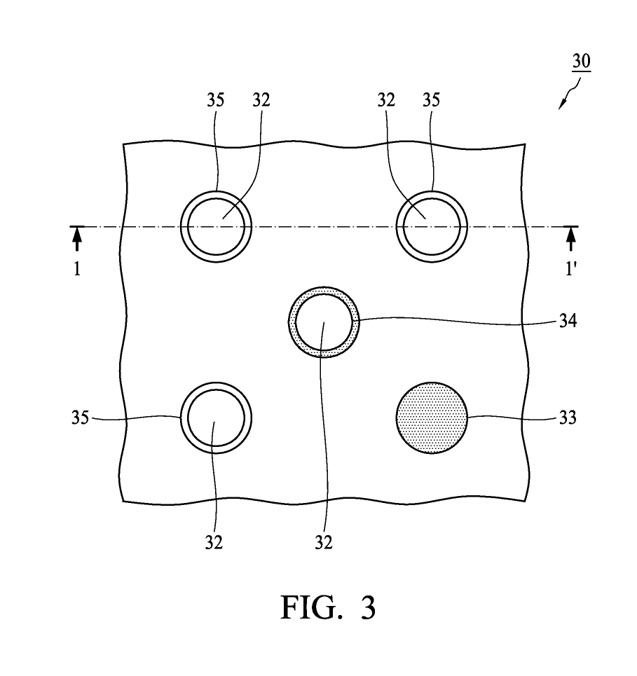

FIG. 3 shows a top view of a portion of a wafer chuck in another embodiment, wherein the portion of the chuck is defined by an area of a single shot shown in FIG. 2, and the portion of the chuck, or a “unit” of the chuck, is equipped with an empty vacuum hole 33, a pin-containing vacuum hole 34, and three pin-containing pin holes 35. In one embodiment of the present invention, a unit 30 of the wafer chuck 11 comprises three types of holes: 1) a vacuum hole 33 similar to the vacuum holes 13 as shown in FIG. 1, without accommodation of any pins; 2) a pin-containing vacuum hole 34, which is not only a through hole like a pin hole, but which contains a pin 32 configured to penetrate through and to be in close contact with the bottom rim of the pin-containing vacuum hole 34 while maintaining the freedom of unidirectional movement. The pin 32 inside the pin-containing vacuum hole 34 has a smaller cross-sectional area than the pin-containing vacuum hole 34, so as to preserve a hollow cylindrical air tunnel for the purpose of vacuum suction; 3) a pin-containing pin hole 35, which is a through hole and contains a pin 32 with a cross-sectional area equal to the cross-sectional area of the pin-containing pin hole 35 that can move freely along the direction perpendicular to the surface of the wafer chuck 11. The purpose of having the pin 32 inside the pin-containing pin hole 35 with equal cross-sectional areas is to prevent the passage of impurities or particles which could affect the precision control of the pin 32. In this embodiment, a unit 30 of the wafer chuck can provide two ways to interact with the wafer thereupon: a suction force employed by the vacuum hole 33 and the pin-containing vacuum hole 34, and a push force employed by the pin-containing vacuum hole 34 and the pin-containing pin hole 35.

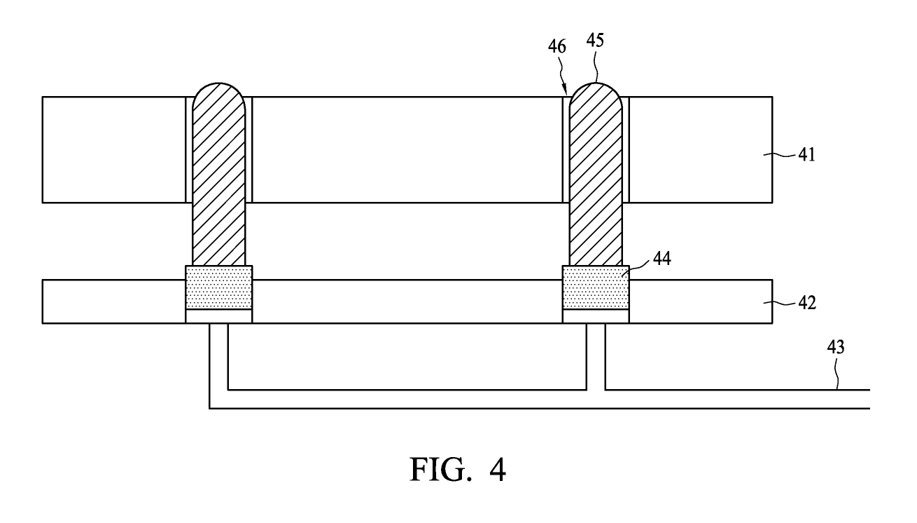

FIG. 4 shows a cross-sectional view along a line 1-1′ shown in FIG. 3. As shown in FIG. 4, two pins 45 are supported by a platform 42 that is disposed under the wafer chuck 41 and extrude from the platform 42 surface through the wafer chuck 41. The size of the pin hole 46 can be in a range of from 5 mm to 10 mm for interaction with, for example, a 12-inch wafer. Each pin 45 can connect to a movable piece 44 that can be moved by controlling the flow of the liquid (not shown) inside, for example, a soft tube 43. The movable piece 44 can be a rigid body functioned as a piston, and the movable piece 44 is large enough to steadily support the pin 45 connected thereon. In this embodiment, the top end of the movable piece 44 can connect to the pin 45 and the bottom end of the movable piece 44 can be subjected to hydraulic pressure. A soft tube 43 can be utilized to carry out the liquid transportation so as to move the movable pieces 44 and pins 45 thereon in a direction perpendicular to the surface of the platform 42. A single soft tube 43 can be disposed in one unit 30 of the wafer chuck 11 such that all of the movable pieces 44 in one unit 30 are either simultaneously protruding from the surface of the chuck 41 to a predetermined position or withdrawing from the surface of the chuck 41 to an original parking position. The tip of the pin 45 is machined to be blunt in order to prevent stress concentration on the wafer created by any sharp edge of the pin 45.

The hydraulic pressure is controlled to fine tune the vertical position of the movable piece 44 within a range of, for example, 0.1 μm . The 0.1 μm displacement is calculated from a parking position of the pins, wherein the parking position is where the top of the pin is at the same level as the surface of the chuck. 0.1 μm is considered to be the maximum required adjustment of the local wafer morphology, so a precise position control is necessary. In another embodiment of the present invention, an electrostatic chuck is used instead of the wafer chuck 11. Every element of the above design can be applied to the electrostatic chuck, except that no vacuum hole exists on the electrostatic chuck and the suction force is replaced by electrostatic force generated between the wafer and the electrostatic chuck. In addition, only the pin-containing pin hole remains on the electrostatic chuck to interact with the wafer positioned thereupon.

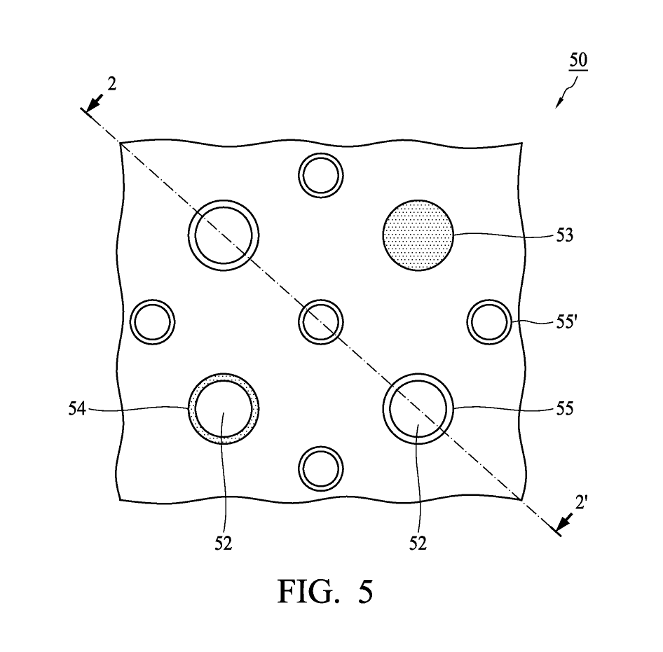

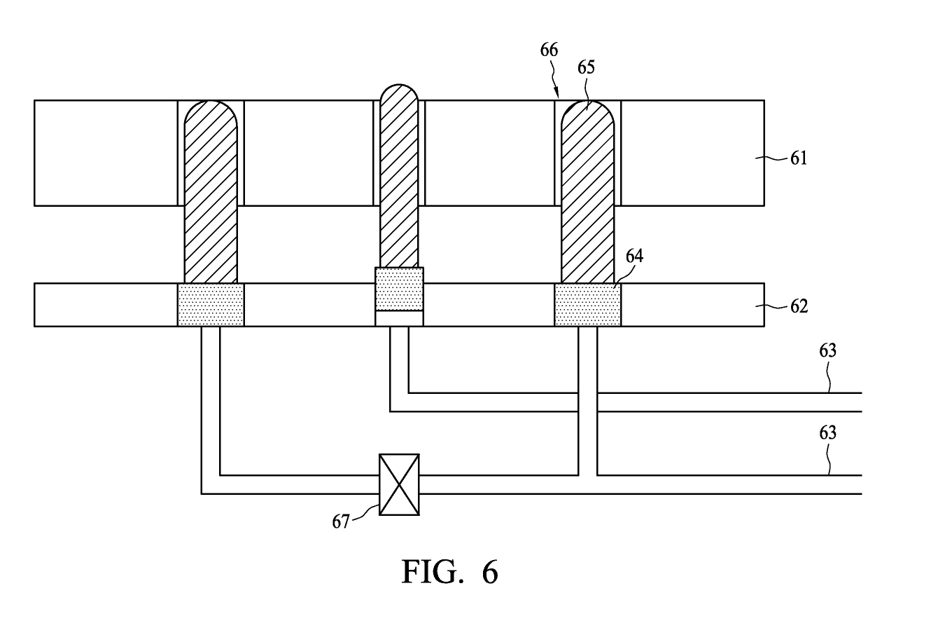

FIG. 5 shows a top view of a unit 50 of a wafer chuck according to another embodiment. The unit 50 of the wafer chuck is equipped with an empty vacuum hole 53, a pin-containing vacuum hole 54, and seven pin-containing pin holes (55, 55′). In another embodiment of the present invention, a unit 50 of the wafer chuck 11 comprises the above three types of holes, while two of the seven pin-containing pin holes are categorized by size as first tier pin holes 55, and the remaining five pin-containing pin holes are categorized by size as second tier pin holes 55′, wherein the cross-sectional area of a first tier pin hole is greater than that of a second tier pin hole. In this embodiment, a unit 50 of the wafer chuck is able to provide two ways to interact with the wafer thereupon: a suction force employed by the vacuum hole 53 and the pin-containing vacuum hole 54, and a push force employed by pins in the pin-containing vacuum hole 54 and the pin-containing pin hole (55, 55′). The two-tier design adds versatility to the tuning ability of the pin-containing pin hole (55, 55′), so that more precise modification to the local morphology of the wafer can be achieved. FIG. 6 shows a cross-sectional view along the diagonal line 2-2′ shown in FIG. 5. In the embodiment of FIG. 6, three pin holes 66 are supported by a platform 62 that is disposed under the wafer chuck 61 and extrude from the platform 62 surface through the wafer chuck 61. The size of the pin hole 66 is in a range of from 5 mm to 10 mm for interaction with a, for example, 12-inch wafer. Each pin 65 can connect to a movable piece 64 that can be moved by controlling the flow of the gas (not shown) inside, for example, soft tubes 63. The movable piece 64 can be a rigid body functioned as a piston, and the movable piece 64 is large enough to steadily support the pin 65 connected thereon. In this embodiment, the top end of the movable piece 64 can connected to the pin 65 and the bottom end of the movable piece 64 can be subjected to pneumatic pressure. Two soft tubes 43 are utilized to carry out the gas transportation so as to displace the movable pieces 64 and pins 65 thereon in a direction perpendicular to the surface of the platform 62. The tip of the pin 65 is machined to be blunt in order to prevent stress concentration on the wafer created by any sharp edge of the pin 65.

The pneumatic pressure is controlled to fine tune the vertical position of the movable piece 64 within a range of 0.1 μm. The 0.1 μm displacement is calculated from a parking position of the pins, wherein the parking position is where the top of the pin is at the same level as the surface of the chuck. 0.1 μm is considered to be the maximum required adjustment of the local wafer morphology, so a precise position control is necessary. In the present embodiment, two soft tubes 63 are connected to pins 65 of different cross-sectional area. As shown in FIGS. 5 and 6, one of the soft tubes 63 is connected to the first tier pins 55, while the other is connected to the second tier pin 55′. Because the sizes and weights of the movable pieces 64 and pins 65 are different, individual pneumatic control of the displacement is necessary. Furthermore, a gas valve 67 is optionally positioned between the soft tube 63 connecting two first tier pins 55 and receives a separate command to open or close, in order to actuate one of the first tier pins 65 or both the first tier pins 65. As such, greater spatial sensitivity can be achieved within the unit 50. In another embodiment, an electrostatic chuck is used instead of the wafer chuck 11. Every element of the above design can be applied to the electrostatic chuck, except that no vacuum hole exists on the electrostatic chuck and the suction force is replaced by electrostatic force generated between the wafer and the electrostatic chuck. In addition, only the pin-containing pin hole remains on the electrostatic chuck to interact with the wafer positioned thereon.

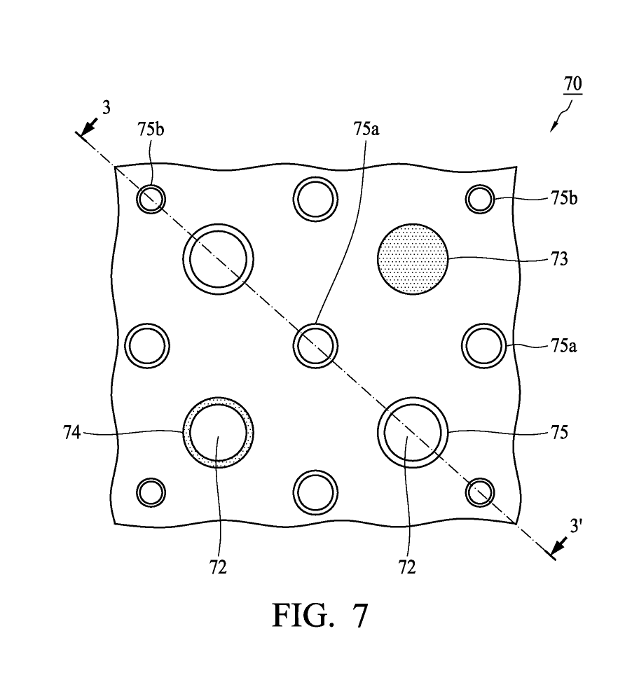

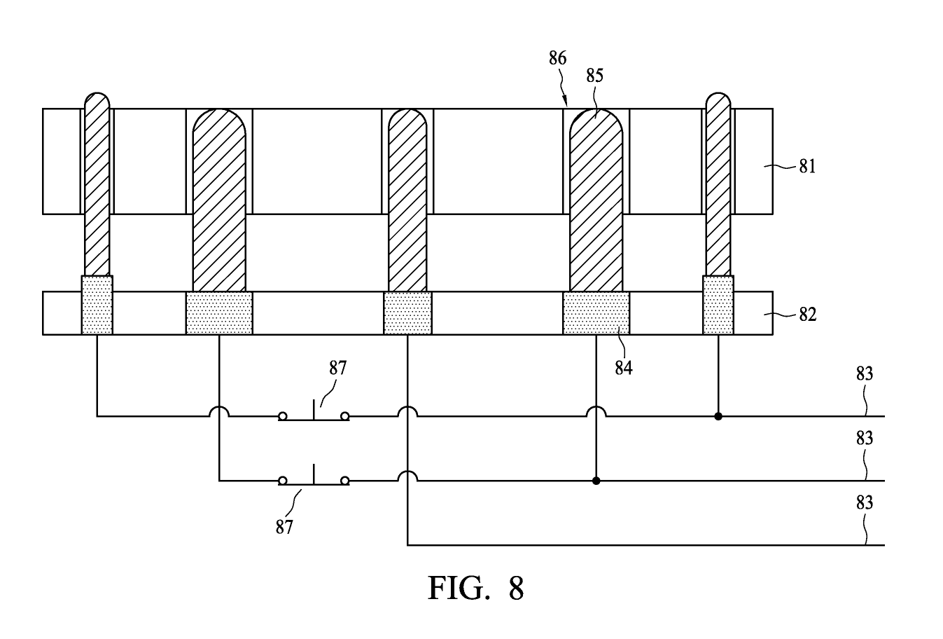

FIG. 7 shows a top view of a unit 70 of a wafer chuck in another embodiment. The unit 70 of the wafer chuck is equipped with an empty vacuum hole 73, a pin-containing vacuum hole 74, and eleven pin-containing pin holes (75, 75a, 75b). In another embodiment of the present invention, a unit 70 of another wafer chuck comprises the above three types of holes, while two of the eleven pin-containing pin holes are categorized by size as first tier pin holes 75, five of the eleven pin-containing pin holes are categorized by size as second tier pin holes 75a, and the remaining four pin-containing pin holes are categorized by size as third tier pin holes 75b, wherein the cross-sectional area of a first tier pin hole 75 is greater than that of the second tier pin hole 75a, and the cross-sectional area of a second tier pin hole 75a is greater than that of a third tier pin hole 75b. In this embodiment, a unit 70 of the wafer chuck 11 is able to provide two ways to interact with the wafer thereon: a suction force employed by the vacuum hole 73 and the pin-containing vacuum hole 74, and a push force employed by pins in the pin-containing vacuum hole 74 and the pin-containing pin hole (75, 75a, 75b). The three-tier design adds even more versatility to the tuning ability of the pin-containing pin hole (75, 75a, 75b), so that more precise adjustment on the local morphology of the wafer can be achieved. FIG. 8 illustrates a cross-sectional view along the diagonal line 3-3′ shown in FIG. 7. In another embodiment of the present invention, five pins 85 are supported by a platform 82 under the wafer chuck 81 and extrudes from the platform 82 surface through the wafer chuck 81. The size of the pin hole 86 can be in a range of from 5 mm to 10 mm for interaction with a, for example, 12-inch wafer. Each pin 85 can be connected to a movable piece 84 that can be moved by controlling an external electric field (not shown) via electrical cords 83. The movable piece 84 is a rigid body functioned as a piston, and the movable piece 84 is large enough to steadily support the pin 85 connected thereon. In this embodiment, the top end of the movable piece 84 can be connected to the pin 85 and the bottom end of the movable piece 84 can be subjected to electricity. In the present embodiment, the movable pieces 84 are made of piezoelectric materials such as PbTiO₃ or the like. Three electrical cords 83 are utilized to apply voltage to the movable pieces 84 so as to induce volume change and to displace the pins 85 thereon in a direction perpendicular to the surface of the platform 82. The tip of the pin 85 is machined to be blunt in order to prevent stress concentration on the wafer created by any sharp edge of the pin 85.

Piezoelectricity is known for its precise actuation ability down to micron level, and is therefore deliberately chosen in the present embodiment to fine tune the vertical position of the movable piece 84 within a range of 0.1 μm. The 0.1 μm displacement is calculated from a parking position of the pins, wherein the parking position is where the top of the pin is at the same level as the surface of the chuck. 0.1 μm is considered the maximum required adjustment of the local wafer morphology, so a precise position control is necessary. In the present embodiment, three electrical cords 83 are connected to pins 85 of different cross-sectional areas, respectively. That is, one of the electrical cords 83 is connected to a first tier pin 75 shown in FIG. 7, while the other two are connected to a second tier pin 75a and a third tier pin 75b. Because the sizes of the movable pieces 84 are different, individual control over voltage is required to induce different volume change. Furthermore, as shown in FIGS. 7 and 8, two switches 87 are optionally positioned between the electrical cords 83 connecting a pair of first tier pins 75 and a pair of third tier pins 75b, respectively. The switches 87 receive a separate command to be on or off, in order to actuate one or both of the first tier pins 75. The same mechanism applies to the control of the pair of the third tier pins 75b. As such, greater spatial sensitivity can be achieved within the unit 70. In another embodiment, an electrostatic chuck is used instead of the wafer chuck 11. Every element of the above design can be applied to the electrostatic chuck, except that no vacuum hole exists on the electrostatic chuck and the suction force is replaced by electrostatic force generated between the wafer and the electrostatic chuck. In addition, only the pin-containing pin hole remains on the electrostatic chuck to interact with the wafer positioned thereon.

In summary, the present invention discloses a wafer supporting structure with pin-containing pin holes. The pins positioned in the pin holes are physically situated on movable pieces of a platform, and the displacement of the movable pieces can be controlled by pneumatic pressure, hydraulic pressure, or electrical bias. The wafer supporting structure comprises a plurality of units, wherein each of the units contains identical sets of pin holes, so the total number of pin holes is an integer multiple of the number of units, or an area defined by a single shot in the photolithography process. After the CD uniformity data is analyzed by a computer program, the data for local morphology correction is sent to actuate the movable pieces and the pins thereon are forced to exert mechanical force to the backside of the wafer.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A wafer supporting structure, comprising:
a chuck comprising a surface configured to support a wafer thereon;
a plurality of pin holes formed through the chuck; and
a plurality of pins received by the corresponding pin holes, independently movable to protrude from or sink into the surface of the chuck.

2. The wafer supporting structure of claim 1, further comprising a plurality of movable pieces configured to move correspondingly the plurality of pins.

3. The wafer supporting structure of claim 2, further comprising a platform positioned under the chuck and supporting the plurality of movable pieces.

4. The wafer supporting structure of claim 2, wherein the materials of the movable piece comprise piezoelectric materials.

5. The wafer supporting structure of claim 4, wherein the pins have a vertical moving range with an upper limit of 0.1 μm relative to a parking position of the pins, wherein the parking position is where the top of the pin is at the same level as the surface of the chuck.

6. The wafer supporting structure of claim 4, wherein the movable piece has one end supporting the bottom of the pin and the other end subjected to an actuating means.

7. The wafer supporting structure of claim 6, wherein the displacement of the movable piece is moved by hydraulic pressure, pneumatic pressure, or electricity.

8. The wafer supporting structure of claim 1, wherein each pin has an axial length greater than the depth of the corresponding pin hole.

9. The wafer supporting structure of claim 8, wherein the pin hole has a diameter in a range of from 5 mm to 10 mm.

10. The wafer supporting structure of claim 1, wherein each pin has a cross-sectional area equal to a cross-sectional area of the pin hole.

11. The wafer supporting structure of claim 1, wherein the total number of pin holes is an integer multiple of the number of shots on the wafer.

12. The wafer supporting structure of claim 1, wherein the chuck comprises a vacuum chuck with a plurality of vacuum holes and an electrostatic chuck.

13. The wafer supporting structure of claim 12, wherein the pin holes are interlaced with the vacuum holes.

14. The wafer supporting structure of claim 12, wherein the vacuum holes comprises at least one pin-containing vacuum hole.

15. The wafer supporting structure of claim 1, wherein the pin has a blunt tip and forms a point contact with the wafer positioned thereon.

16. The wafer supporting structure of claim 1, wherein the pin holes are arranged in a radial fashion.
